(19) United States
(12) Patent Application Publication
(10) Pub. No.: US 2012/0025359 A1
(43) Pub. Date: Feb. 2, 2012

(54) SEMICONDUCTOR DEVICE AND METHOD OF MANUFACTURING THE SAME

(75) Inventor: Kenichi TOMARU, Ota-shi (JP)

(73) Assignee: ON Semiconductor Trading, Ltd., Hamilton (BM)

(21) Appl. No.: 13/188,644

(22) Filed: Jul. 22, 2011

(30) Foreign Application Priority Data
Jul. 30, 2010 (JP) 2010-171322

(51) Int. Cl. H01L 23/495; H01L 21/60

(52) U.S. Cl. 257/675; 438/122; 257/E23.051; 257/E21.506

(57) ABSTRACT

A conventional semiconductor device has a problem that a frame constituting a heat sink is expensive and the heat sink is highly likely to come off a resin package. A semiconductor device of the present invention reduces the frame price because a heat sink is formed by subjecting a frame with a uniform thickness to pressing or something similar. Furthermore, the heat sink is less likely to come off a resin package because step regions of the heat sink are pressed as connection regions to be connected to the other frame in which leads are arranged, and thereby, resin constituting the resin package goes around the step regions and reaches up to back surfaces of the respective step regions. Moreover, a structure which makes the heat sink much less likely to come off is realized because recessed portions are arranged in the step regions of the heat sink.

This application claims priority from Japanese Patent Application Number JP 2010-171322 filed on Jul. 30, 2010, the content of which is incorporated herein by reference in its entirety.

### BACKGROUND OF THE INVENTION

1. Field of the Invention

The present invention relates to a semiconductor device including a heat sink for hear radiation, and a method of manufacturing the same.

2. Description of the Related Art

A structure in which two frames are connected together as described below and a method of manufacturing the structure have been known as a conventional example.

FIG. 8A is a plan view for explaining a frame, in which leads are arranged, out of the two connected frames. A frame 61 is formed, for example, by pressing or etching a thin plate made of a copper-based material (namely, copper or a copper alloy) or the like. Three mount sections 62, indicated with a dotted line, are arranged in the longitudinal direction of the frame (i.e., in the X-axis direction in the drawing). In addition, four through-holes 63 are arranged around the three mount sections 62 in the frame 61. As illustrated, each mount section 62 mainly includes an opening 64 arranged in its center region, multiple leads 65 arranged around the opening 64, and a tie bar 66 for supporting the multiple leads 65.

FIG. 8B is a plan view for explaining a frame, in which heat sinks are arranged, out of the two connected frames. A frame 67 is formed, for example, by pressing a material, such as a copper-based material (namely, copper or a copper alloy), which is good at heat conduction. Three heat sinks 68 are formed in the frame 67. In addition, hanging leads 69 extend from the respective four corner portions of each heat sink 68, and are integrated with the frame 67. Thereby, each heat sink 68 is supported by the frame 67. Four connecting portions 70 are arranged in extremities of hanging leads 69 which correspond to the above-mentioned through-holes 63 (see FIG. 8A), respectively. Protrusions 71 to be inserted in the corresponding through-holes 63 are formed in the connecting portions 70, respectively. Incidentally, a region indicated with a dotted line 72 corresponds to the mount section 62 in the frame 61.

FIG. 8C is a cross-sectional view for explaining how the frames 61, 67 are connected together. In the frame 67 (see FIG. 8B), each heat sink 68 is formed thicker, while each hanging lead 69 and each connecting portion 70 are formed thinner. The protrusions 71 formed in the connecting portions 70 are inserted in the through-holes 63 (see FIG. 8A) of the frame 61, and are subsequently crimped. Thereby, the frames 61, 67 are mechanically connected together. As illustrated, the heat sinks 68 are arranged corresponding to the openings 64 in the frame 61. Incidentally, although not illustrated, semiconductor chips are fixedly bonded to top surfaces of the heat sinks 68, and resin molding is performed with the semiconductor chips electrically connected to the leads 65 by use of metal thin lines. (This technology is disclosed, for instance, in Japanese Patent Application Publication No. 2006-66622, pp. 5-7, and FIGS. 1 to 4.)

### SUMMARY OF THE INVENTION

As described above, the frame 67 is beforehand made, including the thick heat sinks 68, as well as the hanging leads 69 and the connecting portions 70 which are thinner than the heat sinks 68. For this reason, the frame 67 is not versatile. On the other hand, a frame made with a uniform thickness is versatile, because such a frame can be formed in various shapes by pressing, etching or something similar in accordance with its use purpose. As a result, the frame 67 entails a problem that the frame price of the frame 67 is higher than that of the frame made with the uniform thickness. In addition, the frame price of the frame 67 is much higher due to the structure in which the protrusions 71 are beforehand formed in the connecting portions 70 in a way that the protrusions 71 are longer than the through-holes 63 of the frame 61.

Furthermore, each heat sink 68 is shaped like a cuboid, which has a uniform thickness. Each surface of the heat sink 68 is flat. Generally speaking, a resin package having a higher heat radiation capability has a structure in which a ratio of a total volume of the heat sink 68 to a volume of the resin package is accordingly higher, and the heat sink 68 is exposed to the outside through the back surface of the resin package. This causes a problem that an amount of resin constituting the resin package is smaller, thus, the adhesiveness between the resin constituting the resin package and the heat sink 68 is weaker, and accordingly, the heat sink 68 is highly likely to come off the resin package.

Moreover, as is often the case with a structure in which the leads are led out from only one lateral surface of the package, a region in which inner lead portions of the leads are led is placed in the vicinity of the lead-out region. In this case, the inner lead portions are disproportionately placed in that particular region. This disproportionate placement imposes restriction on the directions in which metal thin lines electrically connect the semiconductor chip to the leads. This causes a problem that restriction is imposed on types of semiconductor chips fixedly bonded to the top surfaces of the heat sinks, and the lead frame accordingly lacks in versatility. On the other hand, the metal thin lines need to be connected while three-dimensionally intersecting one another for the purpose of fixedly bonding semiconductor elements having various electrode patterns to the above-mentioned lead frame. This causes a new problem that the loop peak of each metal thin line becomes higher, and it is accordingly difficult to cope with a demand for thinner packages.

The invention provides a semiconductor device that includes a frame having a plurality of leads, a heat sink attached to the frame, a semiconductor element bonded to the heat sink and electrically connected to the leads, and a resin cover covering the semiconductor element so that at least part of a back surface of the heat sink is exposed from the resin cover. The heat sink includes a step portion connected to the frame and elevated from a surface of the heat sink to which the semiconductor element is bonded, an the resin cover covers at least part of the back surface of the heat sink at the step portion.

The invention also provides a method of manufacturing a semiconductor device. The method includes forming a heat sink by pressing a metal sheet so that a step portion elevated from a top surface of the heat sink is formed, that a recess penetrating from a back surface of the heat sink into the step portion is formed and that a protrusion protruding from the step portions is formed. The method also includes forming a frame that comprises leads and a through-hole, attaching the heat sink to the frame so that the protrusion penetrates through the through-hole, crimping a top portion of the protrusion protruding from the step portion, bonding a semiconductor element to the top surface of the heat sink, connecting the semiconductor element electrically to the leads, covering the semiconductor element with a resin so that the back surface of the heat sink is exposed from the resin except for the step portion.

### BRIEF DESCRIPTION OF THE DRAWINGS

FIGS. 1A and 1B are respectively a perspective view and a cross-sectional view for explaining a semiconductor device of the embodiment of the present invention.

FIGS. 2A, 2B and 2C are respectively a plan view, a cross-sectional view and a cross-sectional view for explaining a semiconductor device of the embodiment of the present invention.

FIGS. 3A, 3B and 3C are respectively a plan view, a cross-sectional view and a cross-sectional view for explaining a semiconductor device of the embodiment of the present invention.

FIGS. 4A and 4B are plan views for explaining a method of manufacturing a semiconductor device of the embodiment of the present invention.

FIGS. 5A, 5B, 5C and 5D are cross-sectional views for explaining the method of manufacturing a semiconductor device of the embodiment of the present invention.

FIGS. 6A, 6B, 6C and 6D are cross-sectional views for explaining the method of manufacturing a semiconductor device of the embodiment of the present invention.

FIGS. 7A and 7B are respectively a plan view and a cross-sectional view for explaining the method of manufacturing a semiconductor device of the embodiment of the present invention.

FIGS. 8A, 8B and 8C are respectively a plan view, a plan view and a cross-sectional view for explaining frames used in a semiconductor device of a conventional embodiment.

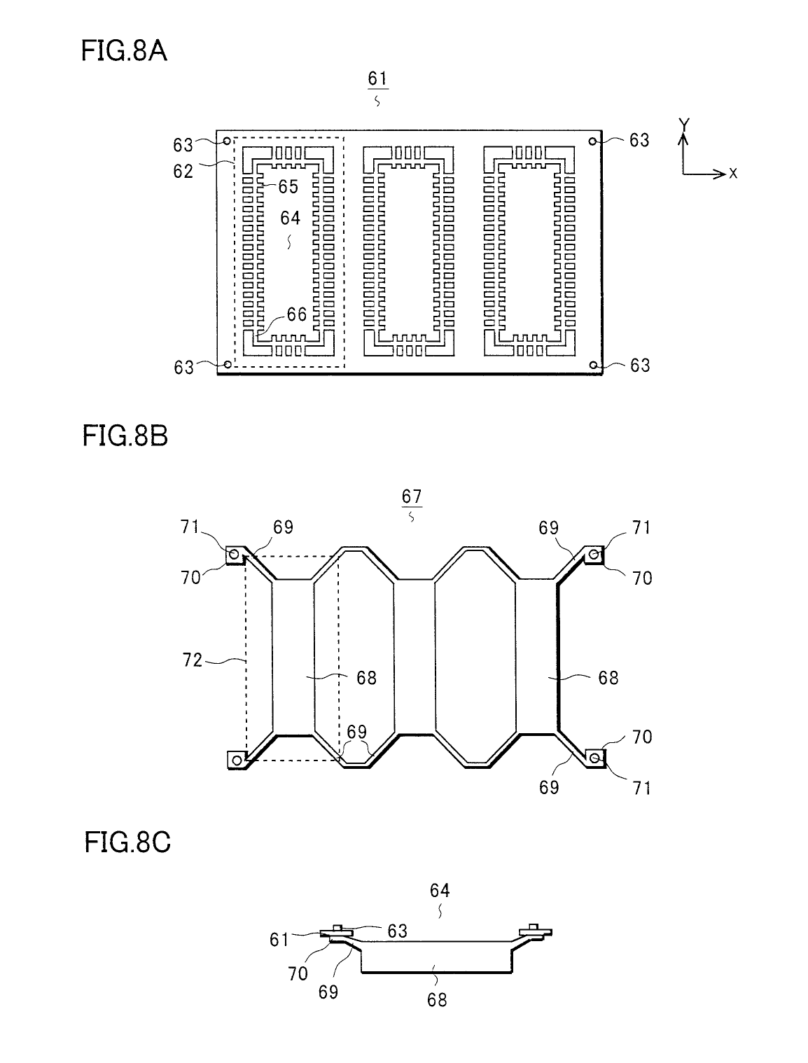

### DESCRIPTION OF THE INVENTION

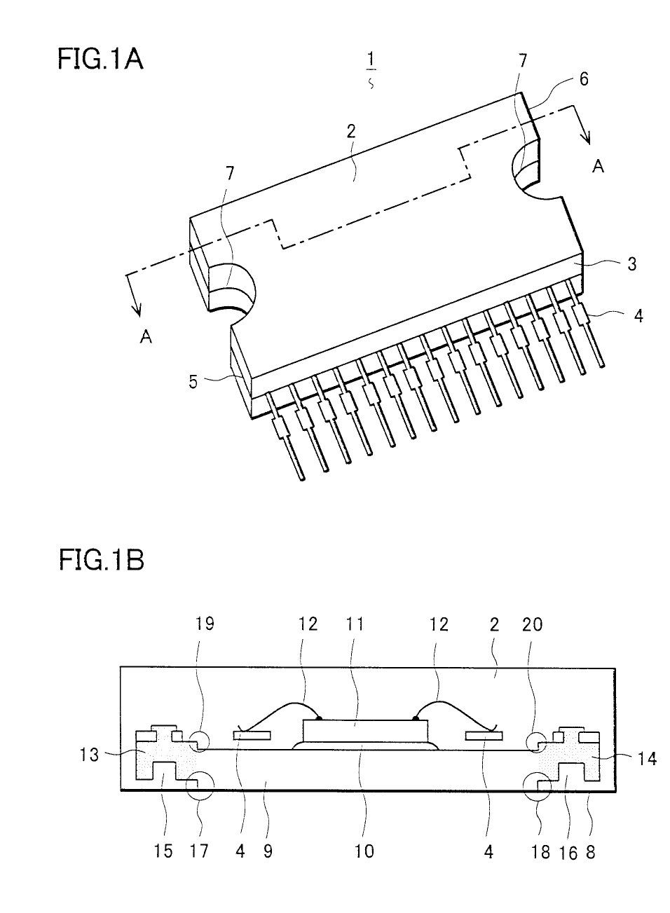

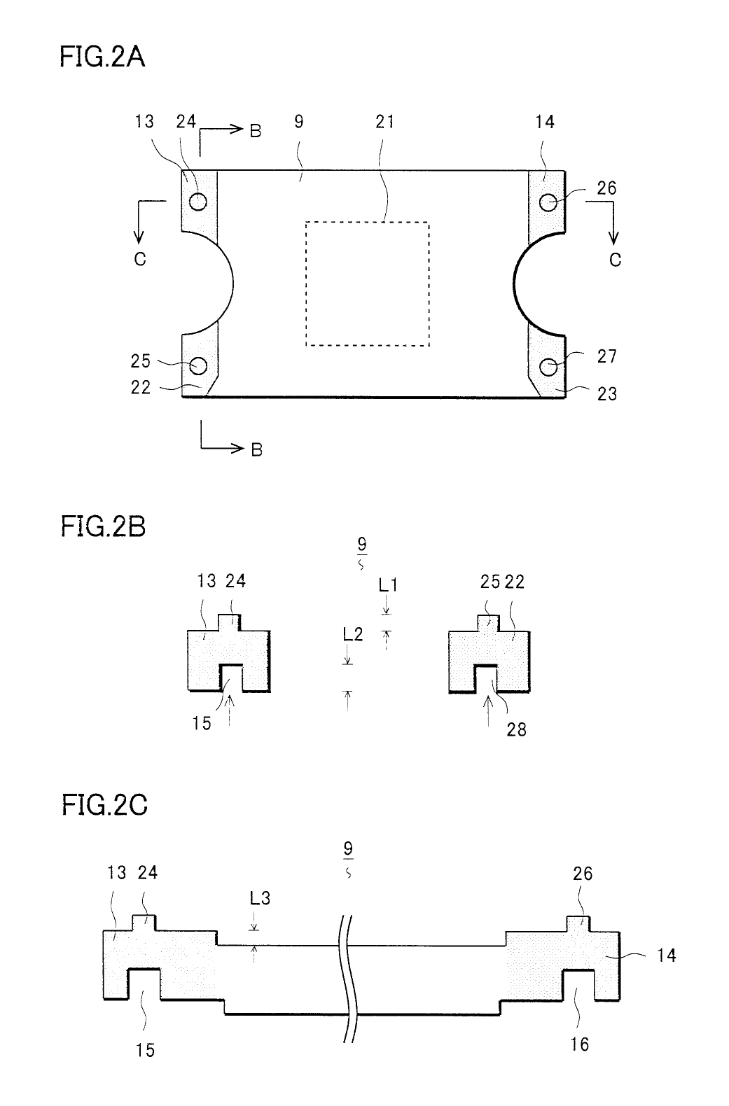

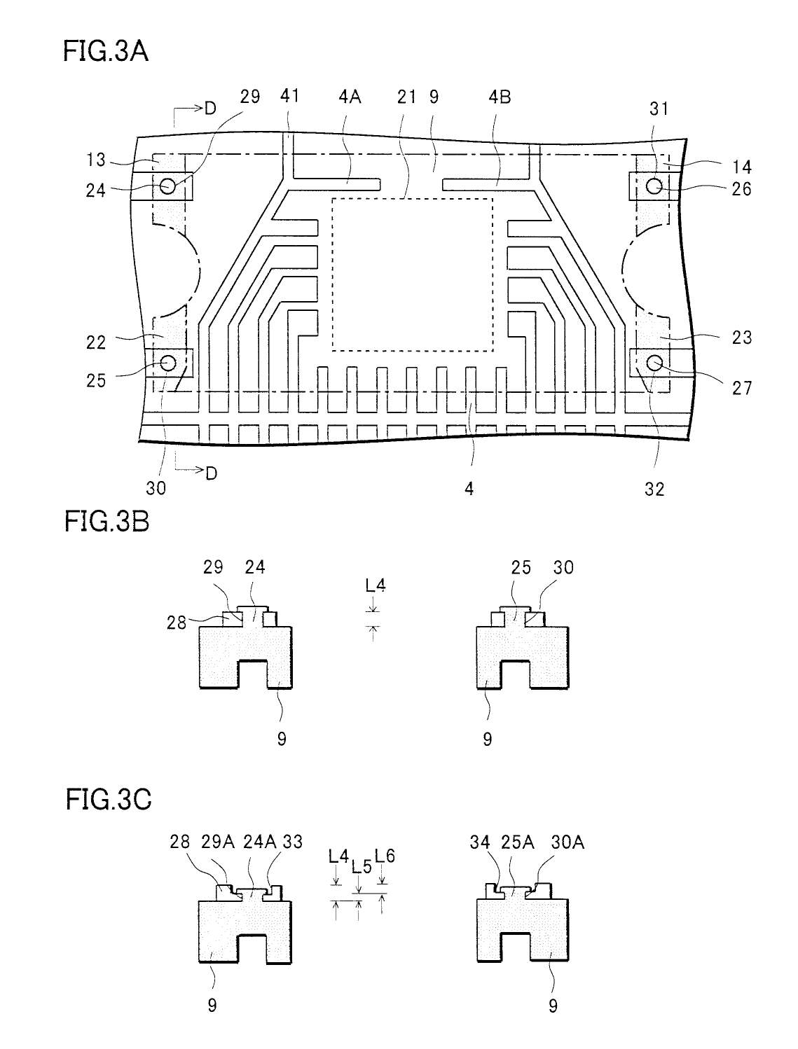

Description will be hereinbelow provided for a semiconductor device of a first embodiment of the present invention. FIG. 1A is a perspective view for explaining the semiconductor device. FIG. 1B is a cross-sectional view of the semiconductor device taken along the A-A line of FIG. 1A. FIG. 2A is a plan view for explaining a heat sink used in the semiconductor device. FIG. 2B is a cross-sectional view of the heat sink taken along the B-B line of FIG. 2A. FIG. 2C is a cross-sectional view of the heat sink taken along the C-C line of FIG. 2A. FIG. 3A is a plan view for explaining a lead structure used in the semiconductor device. FIGS. 3B and 3C are cross-sectional views of the lead structure taken along the D-D line of FIG. 3A.

First of all, as shown in FIG. 1A, multiple leads 4 are led out from a given lateral surface 3 of a resin package 2 of a semiconductor device 1. On the other hand, U-shaped holes 7 for screw-fastening are arranged in lateral surfaces 5, 6 extending in a direction orthogonal to the given lateral surface 3. Incidentally, although not illustrated, the leads 4 are each folded, for example, into a gull-wing shape.

Next, as shown in FIG. 1B, a heat sink 9 is exposed to the outside through a back surface 8 of the resin package 2. A semiconductor element 11 is fixedly bonded to the top of the heat sink 9 by use of an adhesive 10 such as Ag paste or solder. The semiconductor element 11 is electrically connected to inner lead portions of the leads 4 by use of metal lines 12, respectively. For example, gold lines, copper lines or something similar are used as the metal lines 12. Although described in detail later, as marked with hatching, step regions 13, 14 are respectively formed in and around the two longitudinal end portions of the heat sink 9, for example, by pressing. Thus, an anchoring effect is obtained by employing the step regions 13, 14 around which part of the resin of the resin package 2 goes and reaches the back surface of the heat sink 9. In addition, the part of the resin reaching the back surface of the heat sink 9 buries the insides of recessed portions 15, 16 formed in the back surface of the heat sink 9. This enhances the anchoring effect. This configuration realizes a structure in which the area of a part of the heat sink 9 which is exposed to the outside from the resin package 2 is increased and the heat radiation capability is accordingly enhanced, but the heat sink 9 is less likely to come off the resin package 2.

In addition, the heat sink 9 is pressed. Thereby, side surfaces of the step regions 13, 14, which are indicated with circles 17, 18, are turned into sheared sections, while other surfaces of the step regions 13, 14, which are indicated with circles 19, 20, are turned into cut-out sections. This structure enhances the above-mentioned come-off preventing effect further because recesses and protrusions are formed in the side surfaces indicated with the circles 17 to 20, and accordingly, the resin of the resin package 2 is easy to firmly stick to the heat sink 9.

Furthermore, as shown in FIG. 2A, the heat sink 9 is formed, for example, by punching out or pressing a frame with a thickness of approximately 1000 μm, whose main material is copper. For the frame, Fe—Ni may be instead used as the main material. Otherwise, any other metal may be used as the main material. A material exhibiting satisfactory heat conductivity is used as the main material. A region indicated with a dotted line 21 is a fixedly-bonding region to which the semiconductor element 11 (see FIG. 1B) is fixedly bonded, and is arranged under an open area surrounded by the inner lead portions of the leads 4.

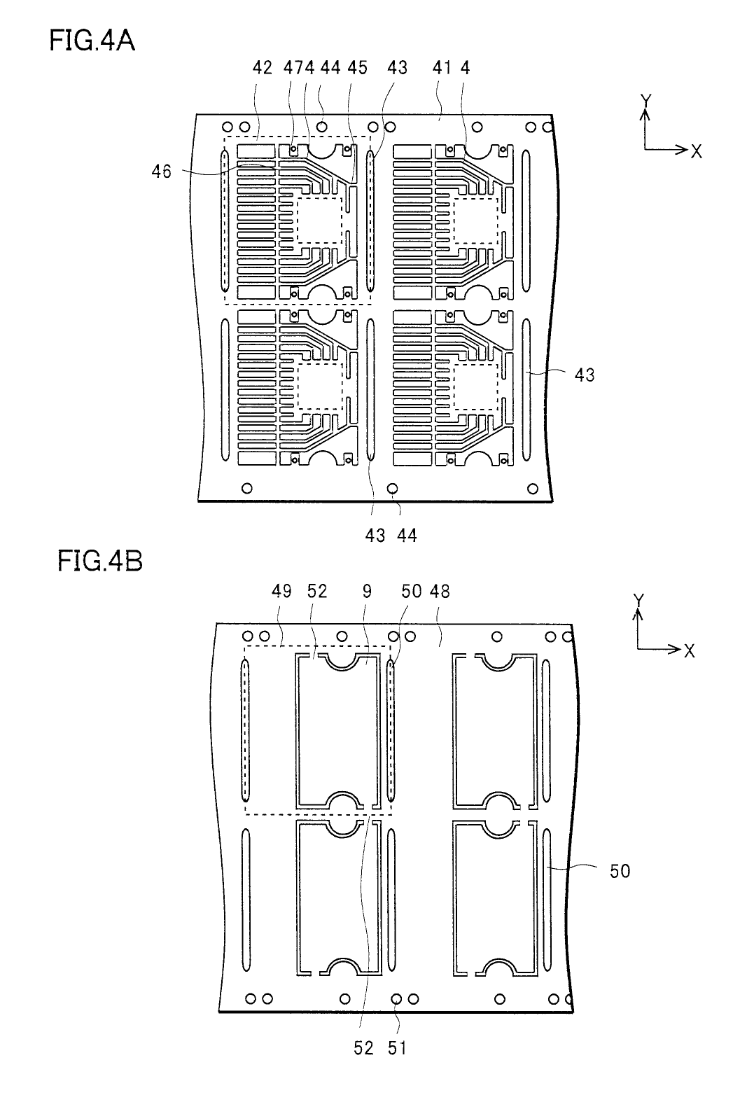

Moreover, regions marked with hatching, which include four corner portions of the heat sink 9 and their vicinities, are the step regions 13, 14, 22, 23. The step regions 13, 14, 22, 23 are used as connection regions to be connected to a frame 41 (see FIG. 4A) in which the leads 4 are arranged. The step regions 13, 14, 22, 23 are formed projecting from the front surface of the heat sink 9 by pressing the heat sink 9 from its back surface toward its front surface. In addition, protrusions 24 to 27 to be inserted in through-holes 29 to 32 (see FIG. 3A) for connection, which are arranged in the frame 41, are arranged in the step regions 13, 14, 22, 23.

Further, as shown in FIG. 2B, the recessed portions 15, 28 are formed in the step regions 13, 22 by pressing the heat sink 9 from its back surface (in directions indicated arrows), respectively. Accordingly, parts of the frame, which are situated over the recessed portions 15, 28 are protruded out. Thereby, the protrusions 24, 25 are formed in the front surface of the heat sink 9. Subsequently, a depth-wise length L2 of the recessed portions 15, 28 is adjusted. A length L1 of the protrusions 24, 25 is made longer than a length L4 (see FIG. 3B) of the through-holes 29 to 32 in the frame 41 in which the leads 4 are arranged. Incidentally, recessed portions and protrusions 26, 27 whose structures are similar to the above-mentioned structures are formed in the step regions 14, 23.

In addition, as shown in FIG. 2C, for the purpose of reducing the price of a frame 48 (see FIG. 4A) in which the heat sink 9 is formed, the heat sink 9 is formed by subjecting the frame with the uniform thickness to pressing or something similar. In addition, the step regions 13, 14 are projected from the front surface of the heat sink 9 by a length L3 by pressing the heat sink 9 from its back surface. The step regions 13, 14 are used as the connection regions to be connected to the frame 41 in which the leads 4 are arranged. This structure enhances mechanical strength of the inner lead portions of the leads 4 because, although explained in detail by use of FIGS. 3A to 3B later, the inner lead portions of the leads 4 are free from folding in exchange of being arranged flatly inside the step regions 13, 14. Incidentally, the step regions 22, 23 have the same structure as does the foregoing step regions 13, 14.

Furthermore, as shown in FIG. 3A, the frame 41 (see FIG. 4A) in which the leads 4 are arranged is connected to the top surfaces of the step regions 13, 14, 22, 23 of the heat sink 9, which is indicated with a chain line. The inner lead portions of the multiple leads 4 are arranged with space between the inner lead portions and the front surface of the heat sink 9. A region indicated with the dotted line 21 represents the fixedly-bonding region to which the semiconductor element 11 (see FIG. 1B) is fixedly bonded. Extremities of the inner lead portions of the multiple leads 4 are arranged around the fixedly-bonding region. As illustrated, some inner lead portions 4A, 4B among the inner lead portions of the multiple leads 4 are led to and arranged in a lateral side opposed to a lateral side through which the leads 4 are led out. This structure enlarges a connection region of the metal lines 12, and thus increases latitude in the connecting directions of the metal lines 12, hence restraining the connection of the metal lines 12 from entailing the three-dimensional intersection among the metal lines 12.

Moreover, the through-holes 29 to 32 for connection are arranged in parts of the frame 41, which are to be situated above the step regions 13, 14, 22, 23 of the heat sink 9, respectively. As illustrated, the protrusions 24 to 27 and the through-holes 29 to 32 are arranged in each mount section, and are placed in the vicinities of the four corner portions of the mount section. This realizes the state in which the frame 41 and the heat sink 9 are stably connected together.

Further, as shown in FIG. 3B, the length L4 of the through-holes 29, 30 is equal to the thickness of the frame 41. The diameter of the through-holes 29, 30 is slightly larger than the diameter of the protrusions 24, 25. Additionally, crimping is performed on the extremities of the protrusions 24, 25 which respectively jut out from the through-holes 29, 30 when they are connected together. This makes a structure which does not allow the protrusions 24, 25 to come off the through-holes 29, 30 because the extremities of the protrusions 24, 25 are crushed flat. Thereby, the protrusions 24, 25 and the through-holes 29, 30 are mechanically connected together.

Instead, as shown in FIG. 3C, a structure may be used in which recessed portions 33, 34 are formed in regions in the frame 41, where through-holes 29A, 30A are to be formed, by superposing the recessed portions 33, 34 on the forming regions from the front surface of the frame 41. The recessed portions 33, 34 are each shaped, for example, like a circular column. The diameter of the recessed portions 33, 34 is larger than the diameter of the through-holes 29A, 30A. To put it specifically, it suffices that the recessed portions 33, 34 have areas for accommodating the crimped extremity regions of the protrusions 24A, 25A, respectively. This helps make a length L5 of the through-holes 29A, 30A shorter than a thickness-wise length of the frame 41 (namely, the length L4 of the through-holes 29, 30). Thus, the length of the protrusions 24A, 25A can be made shorter as well. This structure makes it possible to reduce the thickness of the heat sink 9. Accordingly, this connection structure is usable when a thinner resin package 2 is intended to be made. Incidentally, a depth-wise length L6 of the recessed portions 33, 34 may be arbitrarily changed in design within a range in which the mechanical strength of the connection between the heat sink 9 and the frame 41 can be maintained. In addition, the diameter of the through-holes 29A, 30A is equal to the diameter of the foregoing through-holes 29, 30.

With regard to this embodiment, the foregoing descriptions have been provided for the structure in which the leads 4 are led out from the lateral side 3 of the resin package 2. It should be noted, however, that the present invention is not limited to this case. The present invention may be carried out, for example, as a structure in which the leads 4 are led out from the two longitudinal lateral surfaces of the resin package 2. In addition, the present invention may be carried out as a structure in which the leads 4 are let out from the four lateral surfaces of the resin package 2. Various other modifications may be made within a scope not departing from this gist of the present invention.

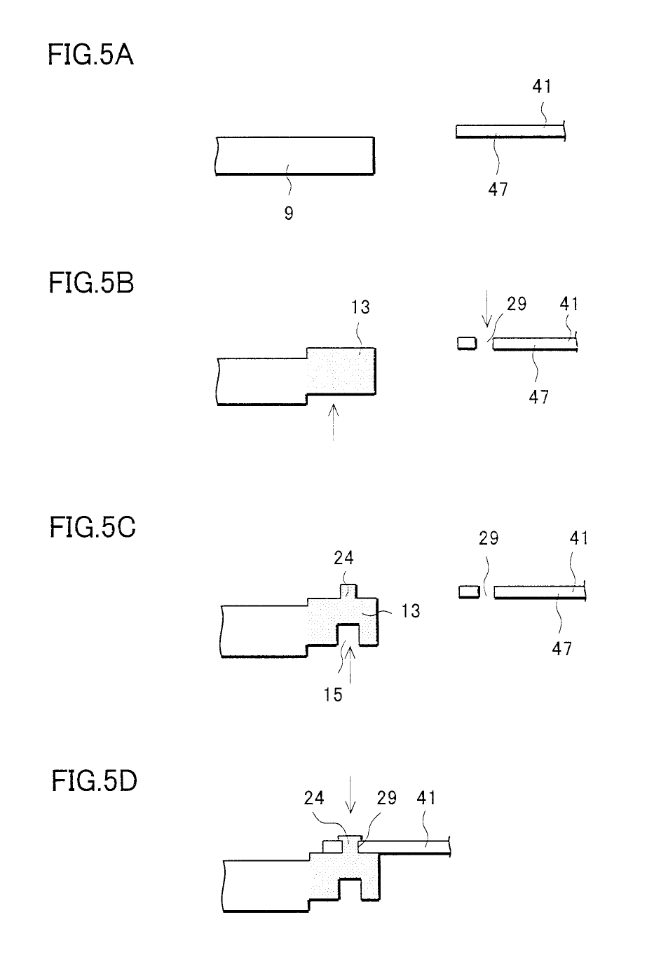

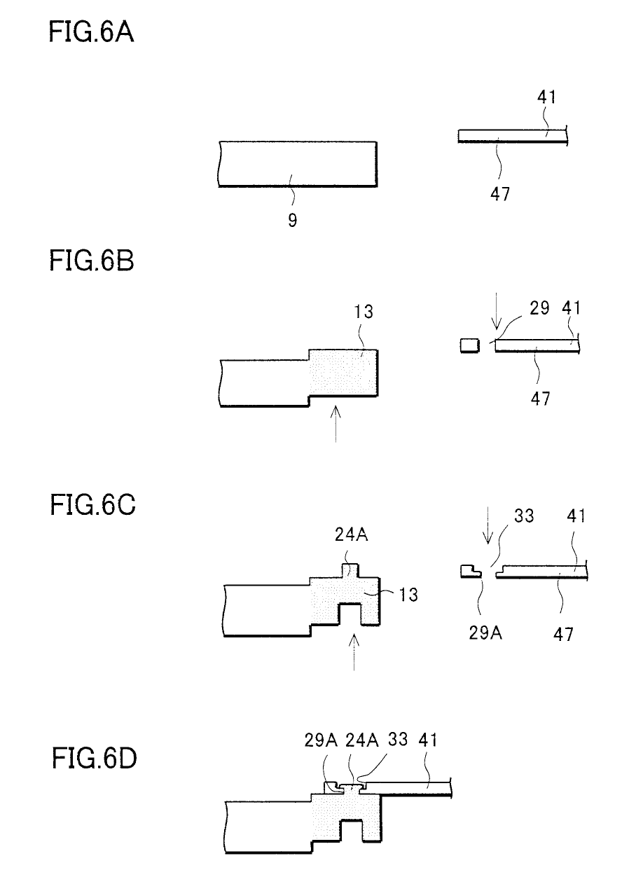

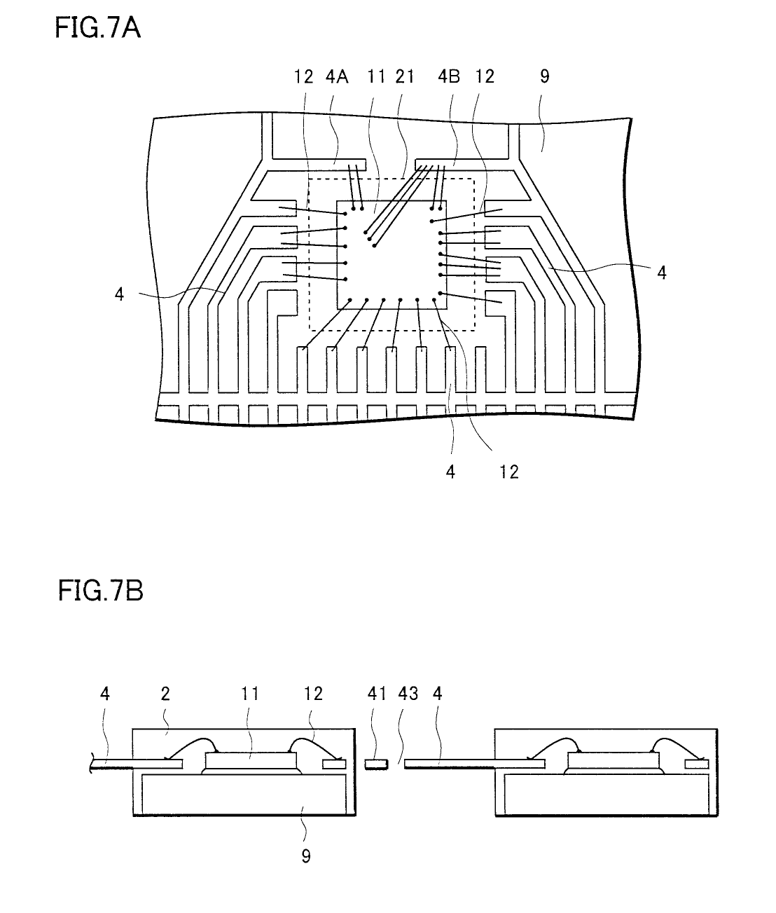

Next, descriptions will be provided for a method of manufacturing a semiconductor device which is a second embodiment of the present invention. FIGS. 4A and 4B are plan views for explaining a frame. FIGS. 5A to 5D are cross-sectional views for explaining a heat sink connecting step. FIGS. 6A to 6D are cross-sectional views for explaining another heat sink connecting step. FIG. 7A is a plan view for explaining a die bonding step and a wire bonding step. FIG. 7B is a cross-sectional view for explaining a resin molding step. It should be noted that for this embodiment, component members which are the same as those shown in FIGS. 1A to 3C will be denoted by the same reference numerals for the purpose of explaining a method of manufacturing the structures shown in FIGS. 1A to 3C, and FIGS. 1A to 3C will be referred to whenever deemed necessary.

As shown in FIG. 4A, a frame 41 with a thickness of approximately 250 μm to 350 μm, whose main material is copper, is prepared, for example. A frame whose main material is Fe—Ni may be used as the frame 41. Otherwise, a frame made of another metal material may be used as the frame 41. Multiple mount sections 42, one of which is indicated with a dotted line, are formed in the frame 41. The frame 41 is partitioned into sections by slits 43 at equal intervals in a longitudinal direction (namely, the X-axis direction in the drawings) of the frame 41. In each section obtained by partitioning the frame 41 by the slits 43, for example, two mount sections 42 are formed in a direction (namely, the Y-axis direction in the drawings) orthogonal to the longitudinal direction of the frame 41. Index holes 44 are provided in upper and lower end areas of the frame 41 at equal intervals in the longitudinal direction of the frame 41, and are used for the positioning purpose in each step.

Each mount section 42 mainly includes multiple leads 4, hanging leads 45 for supporting the leads 4, a tie bar 46 for supporting the multiple leads 4, and four connection regions 47 to be connected to a heat sink 9. The integration of the hanging leads 45, the tie bar 46 and the frame 41 enables the leads 4 to be supported by the frame 41. Incidentally, this embodiment uses a structure in which a semiconductor element is directly mounted on each heat sink 9 with no island formed on the frame 41.

Next, as shown in FIG. 4B, a frame 48 with a thickness of approximately 1000 μm, whose main material is copper, is prepared, for example. A frame whose main material is Fe—Ni may be used as the frame 48. Otherwise, a frame made of a metal material having excellent thermal conductivity may be used as the frame 48. In the frame 48, regions, one of which is indicated with a dotted line 49, correspond to the mount section 42 in the frame 41, one of which is indicated with the dotted line. The heat sink 9 is arranged in each region. The frame 48 is partitioned into sections by slits 50 at equal intervals in the longitudinal direction (namely, the X-axis direction) of the frame 48. Index holes 51 are provided in upper and lower end areas of the frame 48 at equal intervals. In addition, in each section obtained by partitioning the frame 48 by the slits 50, for example, two heat sinks 9 are arranged in the direction (the Y-axis direction in the drawing) orthogonal to the longitudinal direction. The heat sinks 9 are supported by the frame 48 through their respective hanging regions 52.

Next, with regard to the structure shown in FIG. 3B, referring to FIGS. 5A to 5D, descriptions will be provided for processing the frame 41 and the heat sinks 9, as well as a method of connecting the frame 41 and the heat sinks 9 together. Incidentally, FIGS. 5A to 5B show cross-sectional views of one of the four connection regions 47. The other connection regions 47 are processed in the same manner as is the one connection region 47.

First of all, as shown in FIG. 5A, the hanging region 52 (see FIG. 4B) of the frame 48 is cut, and the heat sink 9 is removed from the frame 48. As described above, the heat sink 9 is a plate-shaped body with a uniform thickness, because the frame 48 is formed with the uniform thickness. On the other hand, the flame 41 is handled in a flat-plate condition without being folded for the purpose of enhancing the mechanical strength of the leads 4.

Subsequently, as shown in FIG. 5B, the heat sink 9 is pressed from its back surface (indicated by an arrow). Thereby, a step region 13 of the heat sink 9 is protruded from the front surface of the heat sink 9, for example, by approximately 250 μm. On the other hand, in the frame 41 in which the leads 4 are arranged, the connection region 47 is pressed from the front surface of the frame 41 (indicated by the other arrow). Thereby, a region in which a through-hole 29 is formed is punched out. Specifically, the diameter of the through-hole 29 is approximately 700 μm.

Thereafter, as shown in FIG. 5C, the step region 13 of the heat sink 9 is pressed from its back surface (indicated by an arrow). Thereby, a recessed portion 15 is formed in the back surface of the step region 13. In addition, a protrusion 24 is formed on the front surface of the step region 13 over the recessed portion 15 through this pressing. Specifically, the recessed portion 15 has a shape whose diameter is approximately 750 μm, and whose depth is approximately 600 μm. The protrusion 24 has a shape whose diameter is approximately 650 μm, and which projects from the front surface of the heat sink 9 by approximately 500 μm.

Afterward, as shown in FIG. 5D, the protrusion 24 of the heat sink 9 is inserted in the through-hole 29 of the frame 41. Thereby, the frame 41 and the heat sink 9 are superposed together. After that, the extremity of the protrusion 24, which is led out above the through-hole 29, is crimped. This crimping causes the extremity of the protrusion 24 to alter its shape in a way that the width of the extremity becomes larger than the opening width of the through-hole 29, and thus creates a structure which does not allow the heat sink 9 to come off the frame 41, hence mechanically connecting the heat sink 9 and the frame 41 together.

Next, with regard to the structure shown in FIG. 3C, referring to FIGS. 6A to 6D, descriptions will be provided for processing the frame 41 and the heat sinks 9, as well as a method of connecting the frame 41 and the heat sinks 9 together. Incidentally, FIGS. 6A to 6D show cross-sectional views of one of the four connection regions 47. The other connection regions 47 are processed in the same manner as is the one connection region 47.

First of all, processing work shown in FIGS. 6A and 6B are the same as the processing work shown in FIGS. 5A and 5B. The descriptions made for the processing work shown FIGS. 5A and 5B are extended to the processing work shown in FIGS. 6A and 6B.

Subsequently, as shown in FIG. 6C, in the frame 41, the region where the through-hole 29 is formed is pressed from its front surface (indicated by an arrow). On this occasion, the pressing is performed with a diameter wider than the diameter of the through-hole 29. Thereby, a recessed portion 33 and a through-hole 29A continuing to the recessed portion 33 are formed in the frame 41. Specifically, the through-hole 29A with a diameter of approximately 700 μm is formed up to an area which is away from the back surface of the frame 41 by approximately 150 μm, and the recessed portion 33 with a diameter of approximately 900 μm is formed up to an area which is away from the front surface of the frame 41 by approximately 200 μm. This structure exposes a protrusion 24A to the outside through the through-hole 29A even in a case where the protrusion 24A is made shorter than the protrusion 24, and accordingly makes it possible to reduce the thickness of the heat sink 9. Specifically, the protrusion 24A has a shape whose diameter is approximately 650 μm, and which projects from the front surface of the heat sink 9 by approximately 250 μm.

Afterward, as shown in FIG. 6D, the frame 41 and the heat sink 9 are superposed together. After that, the extremity of the protrusion 24A, which is led out above the through-hole 29A, is crimped. Hence, the heat sink 9 and the frame 41 are mechanically connected together. On this occasion, the crimped portion of the protrusion 24A has a structure in which the crimped portion thereof is accommodated in a region where the recessed portion 33 is formed.

Thereafter, as shown in FIG. 7A, the frame 41 to which the heat sink 9 is connected is placed on a placement stage (not illustrated) of a die-bonder. After that, in each mount section, the semiconductor element 11 is fixedly bonded to the top surface of a fixedly bonding region of the heat sink 9, which is indicated with a dotted line 21. Afterward, an electrically-conductive adhesive such as solder or electrically-conductive paste containing Ag or something similar, or an electrically-insulating adhesive such as an epoxy resin, is used as the adhesive.

Subsequently, the frame 41 to which the semiconductor element 11 is fixedly bonded is placed on a placement stage (not illustrated) of a wire bonder. Thereafter, an electrode pad of the semiconductor element 11 is electrically connected to inner lead portions of the leads 4 by use of metal lines 12, respectively. Starting with the placement of some inner lead portions 4A, 4B, the other inner lead portions of the leads 4 are placed around the entirety of the semiconductor element 11. This enlarges a region where the metal lines 12 are connected to the respective inner lead portions. The increased latitude in the connecting directions of the metal lines 12 allows the semiconductor element 11, to which any one of various electrode pad is placed, to be fixedly bonded to the top of the heat sink 9. In other words, the pattern of the leads 4 no longer needs to be changed depending on what semiconductor element 11 is to be fixedly bonded to the top of the heat sink 9, and the versatile lead frame 41 accordingly can be realized. Furthermore, the metal lines 12 no longer intersect one another three-dimensionally, and the height of the lead peak accordingly can be reduced. This realizes the thinner resin package. Incidentally, for example, gold lines, copper lines or something similar are used as the metal lines 12.

Thereafter, as shown in FIG. 7B, the frame 41 in which each mount section is connected to the corresponding heat sink 9 is placed inside a resin sealing mold (not illustrated). Afterward, the resin is poured into a cavity of the resin sealing mold from a gate portion thereof, and the inside of the cavity is thus filled with the resin. Thereby, a resin package 2 is formed. In a case where the resin package 2 is formed by transfer molding, a thermosetting resin is used. In a case where the resin package 2 is formed by injection molding, a thermoplastic resin is used. For the purpose of enhancing the thermal conductivity, a filler such as silicon oxide may be mixed into the resin constituting the resin package 2.

Finally, for each mount section, the resin package 2 is removed from the frame 41. Subsequently, the outer lead portions of the leads 4 are folded into a gull-wing shape, for example, when a die bar 46 (see FIG. 4A) is punched out. Thereby, the semiconductor device 1 is completed.

As for this embodiment, the foregoing descriptions have been provided for the case in which the heat sinks 9 are removed from the frame 48, thereafter, the heat sinks 9 are pressed, and subsequently, the heat sinks 9 are connected to the frame 41. It should be noted, however, that the present invention is not limited to this case. A scheme may be used in which the heat sinks 9 are pressed while supported by the frame 48, and thereafter, the frames 41, 48 are connected together. In this case, use of the slits 43, 50 and the index holes 44, 51 provided in the frames 41, 48 enables the connecting work to be performed with better positional accuracy. In addition, various modifications may be made within a scope not departing from the gist of this embodiment of the present invention.

The embodiment of the present invention realizes the structure which makes each heat sink less likely to come off the corresponding resin package because the step regions are formed in the heat sink, and part of the resin constituting the resin package goes around the step regions and reaches the back surfaces of the respective step regions.

In addition, the embodiment of the present invention realizes the structure which makes the heat sink much less likely to come off the resin package because the recessed portions are arranged in the back surfaces of the respective step regions in the heat sink.

Furthermore, the embodiment of the present invention increases the mechanical strength of the leads because the frame in which the leads are arranged is not folded in exchange of providing the step regions, and protruding the parts of the heat sink.

Moreover, the embodiment of the present invention can make the thickness of the heat sink thinner, and accordingly realizes the thinner resin package, because the recessed portion is formed in each through-hole forming region in a way that superposes the recessed portion on the through-hole, and thus, the length of the through-hole is made shorter.

Additionally, the embodiment of the present invention increases the latitude in the connecting direction of the metal lines, and accordingly realizes the versatile frame, because the region in which the inner lead portions of the leads are arranged is increased.

Further, the embodiment of the present invention realizes the structure which makes the heat sink less likely to come off the resin package, because the step regions for the respective connection regions are formed by pressing the heat sink.

Besides, the embodiment of the present invention reduces the frame price because a frame with a uniform thickness is prepared, and the heat sink is processed from the frame.

What is claimed is:

1. A semiconductor device comprising:
a frame comprising a plurality of leads;
a heat sink attached to the frame;
a semiconductor element bonded to the heat sink and electrically connected to the leads;
a resin cover covering the semiconductor element so that at least part of a back surface of the heat sink is exposed from the resin cover,
wherein the heat sink comprises a step portion connected to the frame and elevated from a surface of the heat sink to which the semiconductor element is bonded, and
the resin cover covers at least part of the back surface of the heat sink at the step portion.

2. The semiconductor device of claim 1, wherein the step portion includes a first recess penetrating from the back surface into the step portion, and the resin cover fills the recessed portion.

3. The semiconductor device of claim 2, wherein the frame includes a through-hole, the heat sink includes a protrusion disposed on the step portion opposite from the first recess, the protrusion is engaged with the through-hole so that a top portion of the protrusion protrudes from the through-hole.

4. The semiconductor device of claim 3, wherein the frame include a second recess, and the top portion of the protrusion is disposed in the second recess.

5. The semiconductor device of claim 1, wherein the leads comprise outer lead portions protruding from the resin cover and inner lead portions contained in the resin cover, the outer lead portions are disposed only on one side of the resin cover, and the inner lead portions are arranged in a side of the resin cover opposite from said one side.

6. A method of manufacturing a semiconductor device, comprising:
forming a heat sink by pressing a metal sheet so that a step portion elevated from a top surface of the heat sink is formed, that a recess penetrating from a back surface of the heat sink into the step portion is formed and that a protrusion protruding from the step portions is formed;
forming a frame that comprises leads and a through-hole;
attaching the heat sink to the frame so that the protrusion penetrates through the through-hole;
crimping a top portion of the protrusion protruding from the step portion;
bonding a semiconductor element to the top surface of the heat sink;
connecting the semiconductor element electrically to the leads;
covering the semiconductor element with a resin so that the back surface of the heat sink is exposed from the resin except for the step portion.

7. The method of 6, wherein the forming of the frame comprises pressing a frame of a uniform thickness, and the forming of the heat sink comprises punching out the metal sheet.
